(19) United States
(12) Patent Application Publication
(10) Pub. No.: US 2014/0037857 A1
(43) Pub. Date: Feb. 6, 2014

(54) METHODS FOR APPLYING FIXED IMAGES TO ELECTROCHEMICAL DEVICES

(71) Applicants: Mark Allen Cheverton, Mechanicville, NY (US); Neil Anthony Johnson, Niskayuna, NY (US)

(72) Inventors: Mark Allen Cheverton, Mechanicville, NY (US); Neil Anthony Johnson, Niskayuna, NY (US)

(73) Assignee: General Electric Company, Schenectady, NY (US)

(21) Appl. No.: 13/562,622

(22) Filed: Jul. 31, 2012

(51) Int. Cl. B05D 5/12; C23C 16/50; B41J 2/01; C23C 4/12

(52) U.S. Cl. 427/448; 427/58; 427/126.4; 427/586; 427/596; 427/64; 347/101

(57) ABSTRACT

A method for applying a fixed image onto at least one surface of a component in an electrochemical device is described. The component is usually formed of an alumina material. An image-forming material is first applied onto the component surface in its green state. The mark or image is applied in a desired pattern by an additive process, such as direct-write or screen-printing. The component is then heated at a sintering temperature sufficient to ensure conversion from the green state into a fired ceramic state. The sintering temperatures are also sufficient to fix the image upon the surface of the component. The image can be read by the human eye, or by various machine-readable techniques. Related methods for monitoring the location and status of a ceramic electrochemical cell component during its manufacture and during other processing steps are also described.

### BACKGROUND

The present invention is generally directed to an electrochemical cell and related devices, such as high-temperature thermal batteries; and is also related to methods for providing identifying marks on the cell or device.

A battery is an essential component used to store a portion of the energy in mobile systems such as electric vehicles, hybrid electric vehicles and non-vehicles (for example, locomotives, off-highway mining vehicles, marine applications, buses and automobiles); and for stationary applications such as uninterruptible power supply (UPS) systems and “Telecom” (telecommunication systems). As an example, the high-temperature sodium-metal halide electrochemical cells are generally targeted for use in locomotives; telecommunication, and uninterruptible power supply (UPS) batteries. These cells could potentially offer high energy density, high power density, longer cell life, and lower cost-requirements for many of these applications.

In some of the typical sodium-based thermal batteries like the sodium-metal halide devices, the negative electrode is molten sodium, and the positive electrode is nickel (in the discharged state of the battery). The liquid, molten sodium is separated from the positive electrode by a sodium ion-conducting solid electrolyte or “separator”. In many preferred embodiments, the solid electrolyte is formed from beta-alumina. Such a material is exceptionally high in ionic conductivity, i.e., has low electrical resistance, and can also function as a very reliable partition between the positive electrode chamber and the negative electrode chamber. The physical and chemical characteristics of the beta-alumina electrolyte are critical to the overall performance and integrity of these types of batteries.

The beta-alumina separator is usually employed in the general shape of a tube, as depicted in various references, e.g., U.S. 2011/0236743 (Kumar et al). The tube can be fabricated by a number of methods. As one non-limiting example, powders of a sodium compound, an aluminum oxide material such as alpha alumina (α-Al₂O₃), and a metal oxide stabilizer like magnesium oxide, can be mixed in an appropriate ratio. The mixture is then calcined and milled. The resulting material can be granulated, and molded into a desired shape, such as a tube. The “green” tube is then carefully fired at very high temperatures, e.g., above about 1000° C., resulting in the formation of the high-density separator component. Many variations in the overall fabrication process for the separator are possible, as long as the critical properties of the component are maintained. Moreover, large-scale manufacturing processes contemplate the fabrication of thousands of the separator tubes on a regular basis.

In view of the need to fabricate high-quality tubes and other components in a rapid and efficient manner, methods for tracking the tubes during the fabrication process can be very important. This is especially true in the case of energy storage components (such as electrolytes) formed from different types of beta alumina. It is often critical to evaluate the quality and integrity of each beta alumina component as it proceeds through the manufacturing process, since the component plays a large role in the quality of the overall device.

There can be challenges in providing marks and various images to the component, to allow its tracking during manufacturing. For example, the image must be able to withstand the high temperatures needed for manufacturing the component, and for converting the chemical microstructure of the component to a desired form. Moreover, the marking technique should not comprise the integrity of the device. Furthermore, the process for applying the image should not result in contamination of any of the processing systems. The marking technique should also be capable of being carried out at relatively high speeds, and should allow for the deposition of fairly complex images on the component.

### BRIEF DESCRIPTION OF THE INVENTION

In view of the needs described above, various embodiments of a new inventive concept were conceived. One embodiment is directed to a method for applying a fixed image onto at least one surface of a component in an electrochemical device. Usually, the component is formed of an alumina material. The method comprises the following steps:

a) applying an image-forming material onto the surface of the component in its green state, in a desired pattern, by an additive process; and

b) heating the component at a sintering temperature sufficient to ensure conversion from the green state into a fired ceramic state.

Another embodiment of the invention is directed to a method of monitoring the location and status of a ceramic electrochemical cell component during its manufacture, and during additional, optional processing stages. The method comprises the following steps:

(i) forming the component, from a ceramic powder or slurry, into a selected green shape;

(ii) applying at least one identifying mark to a surface of the green component, by an additive process; and

(iii) heating the component at a sintering temperature to convert the component to a fired ceramic state, and to fix the identifying mark to the component surface, wherein the mark is readable by the human eye or by any machine-readable device.

### BRIEF DESCRIPTION OF THE DRAWINGS

FIG. 1 is a cross-sectional view of a portion of an electrochemical cell for some embodiments of the present invention.

FIG. 2 is a general illustration of a direct-write pen system for applying images to the surface of a selected substrate.

FIG. 3 is a perspective of a screen-printing technique for applying images to the surface of a selected substrate.

FIG. 4 is a photograph of a numerical image applied by a direct-write technique, to a selected surface.

### DETAILED DESCRIPTION OF THE INVENTION

Any compositional ranges and temperature ranges disclosed herein are inclusive and combinable (e.g., in the case of composition, ranges of “up to about 25 wt %”, or, more specifically, “about 5 wt % to about 20 wt %”, are inclusive of the endpoints and all intermediate values of the ranges). Weight levels are provided on the basis of the weight of the entire composition, unless otherwise specified; and ratios are also provided on a weight basis. Moreover, the term “combination” is inclusive of blends, mixtures, alloys, reaction products, and the like. Furthermore, the terms “first,” “second,” and the like, herein do not denote any order, quantity, or importance, but rather are used to distinguish one element from another. The terms “a” and “an” herein do not denote a limitation of quantity, but rather denote the presence of at least one of the referenced items.

Moreover, approximating language, as used herein throughout the specification and claims, may be applied to modify any quantitative representation that could permissibly vary without resulting in a change in the basic function to which it is related. Accordingly, a value modified by a term or terms, such as “about,” is not limited to the precise value specified. In some instances, the approximating language may correspond to the precision of an instrument for measuring the value.

A number of components could be marked by a fixed image, according to embodiments of this invention. However, the component is usually one that is formed of an alumina material, such as beta-alumina. Most often (though not always), the component is an electrolyte separator structure, as described previously. The separator is usually shaped and pressed into a green structure or “body”, before the heat treatment (or multiple heat treatments) that will provide it with the necessary density, strength, and microstructural characteristics. In preferred embodiments, the image is applied on at least one surface of the green body, prior to any additional heating steps. (Those skilled in the art are familiar with the “green”, unfired state of ceramic articles). The green body is usually quite fragile in this form, so care is taken in handling the body and applying the fixed image. (It should also be understood that the “fixed” image need not be permanently fixed to the component, e.g., during later use of an electrochemical cell or other device containing the component. In many instances, the image needs to be present only during manufacturing of the component and cell, e.g., for tracking purposes, as described below).

A number of surfaces on the green body could be marked by way of the present invention. In the case of an electrolyte separator structure, the selected surface is preferably one not being used as a specific conductive pathway or ion-carrying path. Moreover, it is usually preferable that the surface to be marked be relatively flat. The additive processes described below are most suited to a relatively planar surface, although in some instances, the images could be applied to curved or irregular surfaces.

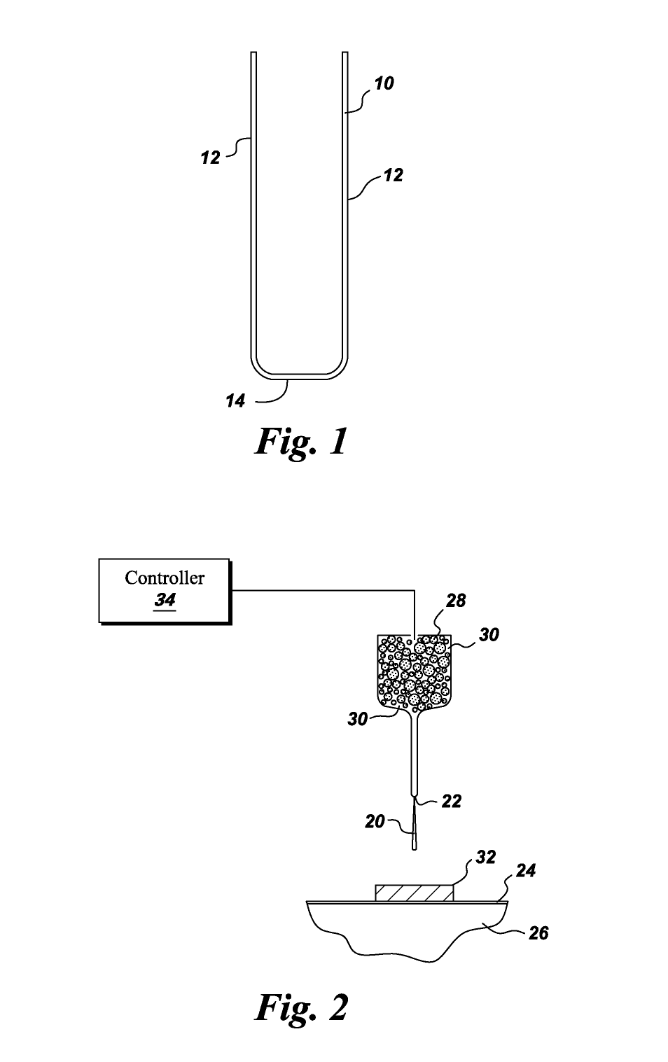

FIG. 1 depicts an ion-conducting separator tube 10. The tube is usually one of the centralized components of an electrochemical cell, and is most often used as a sodium ion-conducting electrolyte. Related electrochemical devices (such as the high-temperature batteries discussed above) are described, for example, in U.S. Patent Publications 2011/0236743 (Kumar et al) and 2010/0178546 (Rijssenbeek et al), both incorporated herein by reference; and pending patent application Ser. No. 13/173,320 (Zappi et al), filed on Jun. 30, 2011, and also incorporated herein by reference. Suitable materials for the separator tube 10 may include beta′-alumina, beta″-alumina, beta′-gallate, beta″-gallate, or zeolite. In some specific embodiments, the separator tube comprises a beta″-alumina solid electrolyte (BASE) material.

In the case of a separator tube like that of FIG. 1, the image can be applied to a number of locations on the surface 12 of the green (unfired) tube. In some embodiments, the bottom surface 14 of the tube can be a suitable location, since it is not usually part of the ion-conductive pathway of the tube, i.e., it may not be an area in which electrochemical reactions are taking place. (The bottom surface also has relatively flat regions in many cases). In other instances, a top region of the tube may be an appropriate location, e.g., at a height greater than about 90% (and sometimes 95%) of the overall height of the tube. (This upper region also may not participate in the electrochemical reaction, because it is usually above the fill-level for the electrode material—cathode or anode, depending on cell design).

The particular type and size of the fixed image can vary greatly, and will depend, in part, on the overall tracking process for the components. The additive processes described below allow for accurate deposition of images in the form of numbers, letters, symbols, bar codes, or any combination thereof.

In some specific embodiments, the image-forming material is very similar in composition to the beta-alumina material from which the component is formed. The similarity can be advantageous for a number of reasons. For example, use of a beta-alumina material for marking reduces the risk of contaminating the overall production environment (e.g., the sintering oven) with foreign substances. As those skilled in the art understand, foreign materials may adversely affect the quality of different types of electrochemical devices.

An image formed from a material similar to the electrochemical cell component material may have greater adhesion to the component, after the sintering process. Such a material will also have a coefficient of thermal expansion (CTE) similar to that of the component. The CTE matching can also enhance adhesion and minimize potential stress points, as well as maintaining the integrity and visibility of the image after the component is fired. In some preferred embodiments, the image-forming material is identical to the material forming the component. For example, both could be formed from beta″-alumina, or from some other form of alumina, e.g., alpha-alumina. (As described below, the image-forming material is most often used in the form of an aqueous or organic-based slurry).

As mentioned above, the fixed image is applied to the surface by an additive process. One example of such a process is a direct-write technique. Direct-write techniques are known in the art and described in many references. Examples include U.S. Pat. No. 6,660,680 (Hampden-Smith) and U.S. Pat. No. 7,302,990 (Bunker et al); and “Direct-Write Technologies for Rapid Prototyping Applications”, edited by A. Pique and D. B. Chrisey, Academic Press, 2002. These documents are all incorporated herein by reference.

As used herein, a “direct-write” technique is a process in which a liquid, liquid suspension, or paste (higher material loading) is deposited onto a surface by ejecting the material through an orifice toward the surface, using a suitable direct-write tool. Usually, the tool itself does not make substantial contact with the surface. The direct-write tool is preferably controllable over an x-y grid relative to the printed surface (i.e., either or both the substrate and the device may move). As mentioned below for various types of direct-write equipment, the tools often also provide control in the “z” direction, thereby allowing compensation for non-planar writing surfaces.

Usually, the image-forming material is initially in the form of a powder, e.g., a ceramic powder comprising beta alumina material. The powder is uniformly distributed in a solvent, forming a slurry (often referred to as an “ink” in the jargon for direct-write processes). The solvent can be organic or aqueous; and may include a number of non-polar or polar types of substances. In some preferred embodiments for the alumina-based, image-forming materials, the solvent is usually aqueous, e.g., water-based.

Various additives may also be present in the slurry. For example, different types of surfactants can be added to impart suitable flow characteristics and other rheological properties to the slurry. Moreover, binders such as starch or cellulose are also frequently used to enhance the integrity of the deposited material, prior to a subsequent heat treatment. The slurry can have a range of viscosities, e.g., from water to tar, depending on various factors. The slurry is preferably well-dispersed, and free of air bubbles and foaming. The slurry should also be chemically stable. Furthermore, when dry, the deposited ceramic material should retain its shape, and possess sufficient strength for subsequent steps involving the electrochemical device, e.g., finishing and handling before firing.

In some preferred embodiments, the image-forming material (e.g., in slurry form) includes at least one colorant, such as a dye, pigment, ink, or paint. In this manner, color is imparted to the fixed image, often making detection and reading of the image an easier task. A number of colorants may be used, with several provisos. First, the colorant should be capable of withstanding processing conditions for the electrochemical cell component. In the case of ceramic components, these conditions may include treatment temperatures (e.g., for curing) that exceed about 1,000° C., and in some cases, greater than about 1,300° C. Many dyes, for example, may vaporize or degrade well below such temperatures. Second, the colorant must not be a material that would chemically degrade the surface or interior region of the component to a substantial degree. A third proviso is that the colorant should not result in significant contamination to the environment in which the cell component is processed or used, e.g., a furnace.

Examples of suitable colorants are the emissive metal oxides, metal salts, and metal halides, such as chromium oxide, potassium chromate; and nickel chloride. These materials may be used either in “neat” form; or may be doped into a matrix material that is stable under harsh environmental conditions, for example, zirconia or alumina. As an example, chromium oxide becomes incorporated into an oxide matrix like alumina, becoming a color center, shifting the absorption spectrum of the chromium oxide, and causing the color shift. The material has a very high emissivity in the visible spectrum. Usually, chromium oxide changes from a green color to a pink color when sintered with the alumina.

Other examples of suitable colorants are high-temperature fluorescent or luminescent dyes. These dyes are known in the art, and are often rare-earth based. Non-limiting examples include rare earth oxides of europium, samarium, terbium, and the like. The materials may also be doped in a suitable matrix for use, e.g., a metal oxide matrix. Fluorescent dyes often emit visible light when exposed to ultraviolet (UV) light. In some instances, it may be possible to use a dye that was photochemically excited at a specific wavelength, but could then fluoresce at a different wavelength, without employing ultraviolet light.

Some examples of suitable colorants are described in pending U.S. application Ser. No. 13/467,139 (P. Singh et al), filed on May 9, 2012, and incorporated herein by reference. The amount of colorant will vary, based on a number of factors, but is usually in the range of about 0.1% to about 30% by weight, based on the weight of the solid constituents in the image-forming material. In some specific embodiments, the level is about 0.1% to about 10% by weight.

The factors that influence slurry composition include the type of direct-write technique employed; and the types of features being formed, e.g., their size, shape, and required integrity. Many of the general details regarding slurry formation are known in the art and need not be described extensively here. Reference is made to various sources for ceramics processing, such as the “Kirk-Othmer Encyclopedia of Chemical Technology”, 4th Edition, Vol. 5, pp. 610-613″, and U.S. Pat. Nos. 6,613,445 and 5,985,368 (both to Sangeeta et al, and incorporated herein by reference). The slurry or ink is usually applied directly onto the desired substrate, in an automated technique. Usually, a CAD/CAM interface is employed to program a desired pattern for the deposition.

A number of direct-write processes are suitable as the additive process for embodiments of this invention. Examples include thermal spray, laser CVD, ink jet, laser particle guidance, matrix assisted pulsed laser evaporation (MAPLE), pen dispensing techniques, and combinations of any of the foregoing. They are generally known in the art, e.g., as shown in the references set forth above. Several of the techniques of particular use for this invention will be described in some detail

Ink-jet techniques are described extensively in the Pique/Chrisey text (e.g., Chapter 7), and in many other references, e.g., the “Kirk-Othmer Encyclopedia of Chemical Technology”, 4th Edition (1996), Vol. 20, pp. 112-119. Various ink jet systems can be employed, as long as they can accommodate the image-forming material, e.g., in slurry form. The ink-jet techniques are usually continuous mode systems or demand-mode (e.g., impulse) systems. Within the latter category, there are various types of impulse systems as well, e.g., piezoelectric systems and thermal impulse systems. The electronic control mechanisms for ink jet systems are also well-understood in the art. Various computer-control systems can be employed, e.g., using a CAD/CAM interface in which the desired pattern of deposition is programmed.

Those skilled in the art are familiar with the requirements for ink compositions, which can usually be aqueous or solvent-based. In addition to some of the additives mentioned above, ink jet compositions may contain other ingredients which are somewhat particular to this deposition method. For example, humectants and selected co-solvents may be used to inhibit drying of ink in the nozzles. The composition of the ceramic slurries used according to this disclosure can be readily adjusted to be compatible with ink jet deposition.

Laser-guided direct writing (LGDW) can also be used to apply the image-forming material to the desired substrate. In a typical process of this type, a stream of deposition particles is produced, as described in the Pique/Chrisey text (e.g., pp. 10 and 646-648). The particles are constrained by a laser beam, and directed onto a selected region of the substrate. The particles often originate as suspensions, e.g., a suspension in water. In some instances, ultrasonic atomization is used to spread the particles in the atmosphere, for contact with the laser beam.

Laser particle guidance systems and related details are also described in U.S. Pat. Nos. 6,636,676 and 6,268,584, which are incorporated herein by reference. As described in the latter patent, the laser particle guidance systems typically include various positioning mechanisms, which are computer-driven to direct the pattern of deposition. Some of the LGDW systems are commercially available from Optomec Design Company, Albuquerque, N. Mex.

The “MAPLE” technique is another example of a direct-write process suitable for embodiments of the present invention. (The acronym corresponds to “matrix assisted pulsed laser evaporation”). The MAPLE technique is described in considerable detail in the Pique/Chrisey text (e.g., pp. 138-139; 521 et seq.). The technique is also described in U.S. Pat. Nos. 6,660,343 and 6,025,036, both incorporated herein by reference.

In brief, MAPLE uses a focused ultraviolet laser pulse to transfer material from a coating on a carrier, onto a substrate. In one type of MAPLE system, the laser impacts the material to be transferred from the back at the carrier-material interface, through the carrier (which is usually transparent). The material is designed to absorb the laser energy, causing local evaporation at the interface. Discrete “packets” of the deposition material are thus propelled toward the substrate, according to a computer-controlled pattern. By using a sequence of laser pulses while moving one or both of the carrier and the substrate, a desired pattern can be directly written.

Those skilled in the art will be able to adjust the characteristics (e.g., particle size and rheology) of the ceramic composition used herein, to be compatible with the MAPLE process. Various other process parameters can also be adjusted by those familiar with MAPLE. Examples of the parameters include incident beam energy, pulsed laser rate, and the like.

Pen-dispensing systems represent another class of direct-write techniques, and they are often preferred for the present invention. The systems often use automated syringes, and are sometimes generally referred to as “micropen printing” processes. The referenced Pique/Chrisey text provides a general description of these systems (e.g., chapter 8); they are also mentioned in the above-referenced Hampden-Smith patent. Some of the process factors mentioned above are relevant here as well, such as the rheology of the printing paste or ink, as well as its wetting and adhesion characteristics. Commercial pen-dispensing systems are available from various sources. For example, the Micropen™ tool is available from Ohmcraft, Inc., of Honeoye Falls, N.Y. The Dotliner™ dispense system is another commercially-available product.

An illustration of one type of pen-based deposition process is provided in FIG. 2. A mixture 20 of the deposition material is delivered through a nozzle or “pen” 22 onto surface 24 of a component 26 of an electrochemical device. The mixture 20 is usually a ceramic slurry, comprising ceramic powder 28 dispersed in a liquid medium 30. (The viscosity of the slurry is sometimes very high). Mixture 20 can be forced through nozzle 22 at a controlled rate, to achieve a desired shape and size for positive feature/image 32. One or more passes with the pen may be made on the surface. The size of the orifice of the nozzle (along with other factors mentioned below) is selected to provide a desired dimension for each pass.

During deposition of the material, nozzle 22 is displaced relative to component surface 24, so as to form feature 32 with a pre-determined shape/identifying mark. (As alluded to above, the pre-determined shape is generated and stored in a computer, e.g., as a CAD/CAM file). The “displacement” is carried out by moving the nozzle or the component, or moving both, with computer control. An exemplary controller is generally depicted as element 34. The height and shape of the features deposited on the surface are determined in part by the flow-rate of the dispensed material stream, and the relative speed of movement between the pen tip and the workpiece (i.e., the electrochemical cell component) during the writing operation.

In some instances, it may be desirable to apply the identification image to a curved surface of the component. The pen processes described above can effectively deposit the desired ceramic material on most sections of these curved surfaces, as well as any irregular surfaces. However, it is sometimes desirable to use other types of pen systems to efficiently deposit the desired material on many additional surface regions of the component.

A suitable pen system that can produce a fixed image of 3D configuration is described in U.S. Pat. No. 7,302,990 (Bunker et al). The system, colloquially referred to as a “robotic pen”, is computer controlled. It includes a multi-axis stage for mounting a workpiece (i.e., the electrochemical cell component in this instance), and a cooperating elevator for providing vertical motion to the workpiece. Usually, the pen tip is rotatably mounted to the elevator. A dispenser for providing the deposition material is joined in flow communication to the pen tip. The dispenser ejects a stream of material to the surfaces of the workpiece as the workpiece moves relative to the pen. The elevator introduces a vertical axis (Z) of translation relative to a workpiece stage, with three axes of translation (X, Y, Z) and one rotary axis (A), as depicted in the referenced patent.

While direct-write techniques may be preferred in some cases, another additive process suitable for embodiments of this invention is screen-printing. Screen-printing techniques are known in the art, and are described in a number of references. They are sometimes referred to by other names, such as silkscreen, serigraphy, and serigraph printing. In general, the techniques rely on the use of a woven mesh or screen, to support an ink-blocking stencil.

The stencil includes open areas of the mesh that allow ink or other image-forming materials to be transferred through the mesh, and onto the desired substrate, e.g., an electrochemical component surface. In most embodiments, a fill-blade or squeegee is moved across the screen stencil, forcing the image-forming material into the mesh openings for transfer by capillary action, during the squeegee stroke. Three types of screen-printing platforms (i.e., screen-printing presses) are commonly used in the art: flat-bed, cylinder, and rotary presses.

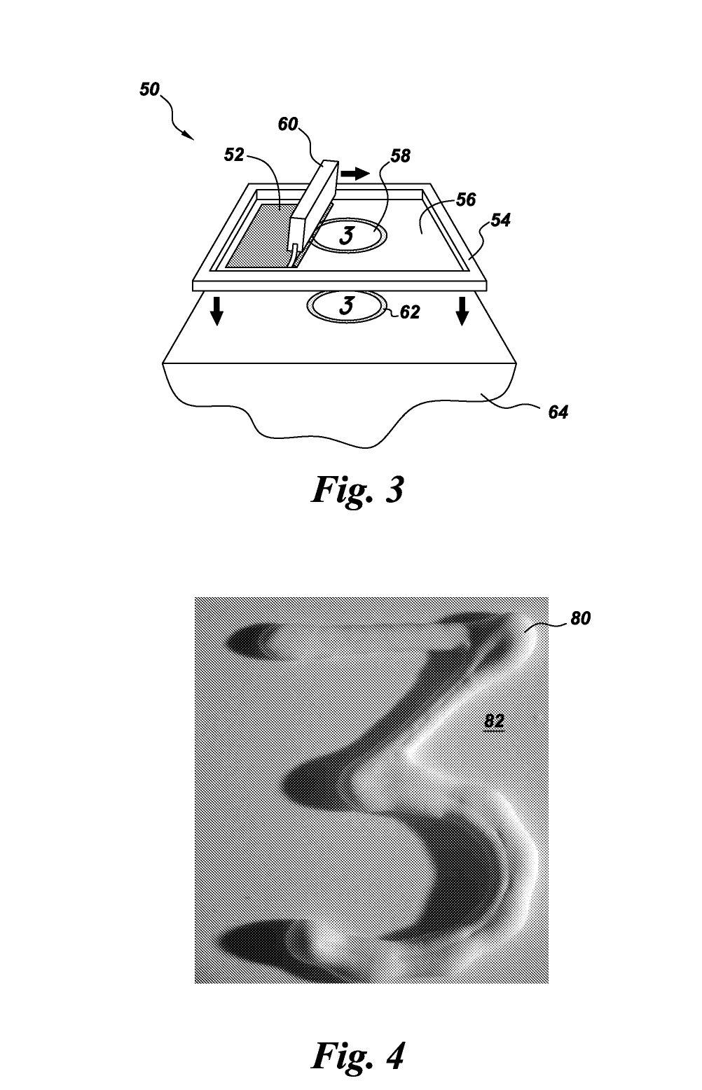

FIG. 3 is a simplified depiction of one type of screen-printing apparatus 50. A reservoir of image-forming material 52 (e.g., ink) is contained within the screen-printing frame 54. The actual screen 56 (which might be referred to as an “image plate”) typically includes a stencil that defines a desired image 58. The image can be produced on the screen either manually, or photochemically. In the latter case, the image can be formed on the screen by the use of a pre-press technique, in which a photo-emulsion is first spread across the mesh area. A heat treatment can then be used to burn away the unnecessary emulsion, leaving behind a clean area in the mesh with the identical shape of the desired image. Using the squeegee 60 that is drawn across the screen 56, the ink 52 can then be forced through the mesh openings (not specifically shown) of the screen 56, by applied pressure. The ink will pass through only in those areas where no stencil has been applied, thereby forming the desired image 62 on the substrate 64.

Those skilled in the art are familiar with other details regarding screen printing, e.g., selection of the threads and thread count of the screen 56, to determine how much image-forming material is to be deposited on the substrate. Other factors include the viscosity and composition of the image-forming material; as well as the size, shape, pressure, and speed of the squeegee 60. All of these factors can influence the quality of the impression made on the substrate. Moreover, automated screen-printing processes can also be used in some embodiments of this invention.

FIG. 4 is an example of a fixed image 80, applied to a test-substrate 82 by an additive process. The image, in the shape of the numeral “3”, was formed from a beta alumina material. This character was deposited, using a Nordson EFD Ultra 2400 series air-pump. A 30 cc syringe was used to hold the slurry. The delivery device included a stainless steel nozzle, having a diameter of about 0.013 inch (0.33 mm). The pump was set to 35 psi for the deposition. While the figure shows only one of the characters, other images were also deposited, such as a six-element character string, “1234AB”. The character size was about 2 mm wide, and 3 mm in height. In the multi-element marking, the characters were separated by a distance of about 0.5 mm. However, it was also determined that all of the dimensions of the characters, and the character spacing and pattern, could readily be varied to meet the needs of a given situation.

The height and width of the image will depend on a number of factors. They include the manner in which the image will be read and inspected, e.g., by the human eye, or by one or more image-scanning techniques, such as the use of camera-based readers (for example, barcode readers), or any OCR (optical character recognition) technique. For simplicity, all of these techniques can be referred to as “machine-readable” techniques. The presence of a colorant in the image can also be a factor in determining the best size for the fixed image; as can the general processing conditions for manufacturing the electrochemical device. The design of the image (e.g., one having may individual numerical digits) may also be a factor in determining image size. In some specific examples for manual inspection (with the human eye), the height of the image will usually be in the range of about 10 mm to about 15 mm. When the image is formed on the outside surface of a hollow or partially-hollow tube or similar article, it may sometimes be possible to shine light within (or from inside) the article, to increase the visibility of the image from the outside of the article.

As mentioned above, the component on which the image is being applied can be formed from an alumina material, such as alpha alumina (α-Al₂O₃) or one of the beta alumina compounds. In some instances, beta″ alumina (sometimes referred to as “beta prime-prime alumina” or β″-alumina), an isomorphic form of aluminum oxide, is especially preferred for use in components related to energy storage devices, such as the nickel metal halide batteries. The beta″ alumina, e.g., formed commercially by a calcination process and/or other techniques, can be used in powder form as a constituent to initially form the component by a molding technique. As described previously, a green form of the component is thus formed.

Alternatively, alpha alumina can be used initially to form the green component. After heating and sintering at temperatures in the range of about 1,200° C. to about 1,700° C. for about 12 hours to about 48 hours, the alpha alumina in the component is converted into the beta″ alumina form. Those skilled in the art understand that the sintering schedule can be varied, in terms of time, temperature, cycles, and the like. Moreover, the general heating step(s) involved with ceramics may involve a number of significant changes to the alumina material, e.g., chemical reactions via decomposition and/or oxidation; and/or phase transformations, as well as the sintering itself. Sintering is a phenomenon whereby compacted powders will bond when heated to temperatures at some pre-determined level below their melting temperature. Sintering usually converts highly-porous compacted powders into high strength bodies. The strengthening is apparently due to the formation of inter-particle bonds, resulting from motion at the sintering temperature. Although the inventors do not wish to be bound by any particular theory, it is thought that sintering is driven by particle diffusion, leading to a reduction in surface energy, which can occur by various mechanistic pathways.

In some instances, the green, unfired alumina component is partially in beta″ alumina (β″-alumina) form. For example, about 85-90% of the alumina could be in such a form, with the remainder being in the alpha-form, or another isomeric form. The component is then heat-treated under conditions sufficient to ensure conversion to at least about 95% of the beta″ form, and in some preferred embodiments, at least about 98% of the beta″ form.

As alluded to previously, the identification-image on the electrochemical cell component must withstand all heat-treatments and any other processing steps. This is especially critical when the image is being applied to beta″ alumina components for batteries, or to components that will be chemically converted to beta″ alumina. The beta″ alumina structure (often in the form of its molten salt analogue, sodium aluminate) plays a critical role in ionic conduction within the battery cells. Reliable identification of each cell by a technique that does not adversely affect the treatment or properties of the cell can be a very important aspect of an industrial manufacturing process.

As mentioned previously, the electrochemical device (or a component thereof) that is marked and identified according to this invention is often an energy storage cell, e.g., a battery. These types of devices are described in a variety of references. One non-limiting example is U.S. Pat. No. 7,632,604 (Iacovangelo et al), which is incorporated herein by reference. The patent describes various device configurations. For example, a battery may be contained within a housing that includes a separator, like those mentioned previously. (The separator/electrolyte, prior to incorporation into the battery structure, is often the component that requires marking for identification).

The outer surface of the separator may define a first chamber, which can function as the anode, e.g., a chamber containing sodium in the case of a sodium metal halide battery. The inner surface of the housing defines a second chamber, e.g., a cathode chamber that contains one or more metal salts. (The specific contents of each chamber depend on the charge-state of the battery). The chambers are in ionic communication with each other through the separator. The chambers also include current collectors to collect the current produced by the device.

Other details regarding electrochemical cells and nickel-metal halide batteries are known to those skilled in the art, and are described in many references, e.g., “Advances in ZEBRA Batteries”, Cord-H. Dustmann, Journal of Power Sources, 127 (2004) pp. 85-92; U.S. Patent Publication 2010/0086834 (Mahalingam et al, also incorporated herein by reference); and the above-referenced U.S. Pat. No. 7,632,604. Methods for their manufacture and use are also known in the art. As described above, the ability to identify and track key components of these devices—especially during manufacture—can be an important factor, in terms of product quality and process efficiency.

Another embodiment of this invention is directed to a method of monitoring the location and identity of a ceramic electrochemical cell component during its manufacture and/or incorporation into another device. The component can be an electrolyte structure, e.g., an alumina-based separator tube for an energy storage device, such as a battery. The method comprises the step of forming the component from a pressed-powder, in a desired, “green” shape. (The component is often formed from a slurry of the ceramic powder(s), using known techniques).

An identifying mark is then applied to a surface of the green component, by an additive process, such as direct-writing or screen-printing. The component is then sintered under appropriate heating conditions. The identifying mark can be scanned by the human eye, or by electronic/optical techniques, as discussed previously.

This method allows one to “track” the movement of the component through an overall manufacturing process, and to determine various materials and conditions associated with the component. For example, the type and batch of ceramic powder used to form the identified component can be compared with the resulting physical properties and overall quality of the component, e.g., its hardness, density, purity, and the like. The processing conditions (e.g., temperature, environmental, processing speed and the like) can also be tracked to the specific, identified component, showing what effect those conditions had on the component. The ability to track a specific component in an overall manufacturing process, e.g., one used to fabricate thousands of components and related devices, can be of considerable commercial value.

The embodiments described herein are exemplary. This written description may enable those of ordinary skill in the art to make and use embodiments having alternative elements and features that likewise correspond to the elements and features of the invention recited in the claims. The scope of the invention thus includes those alternatives.

What is claimed:

1. A method for applying a fixed image onto at least one surface of a component in an electrochemical device, said component being formed of an alumina material, comprising the following steps:
a) applying an image-forming material onto the surface of the component in its green state, in a desired pattern, by an additive process; and
b) heating the component at a sintering temperature sufficient to ensure conversion from the green state to a fired ceramic state.

2. The method of claim 1, wherein the image-forming material also comprises an alumina material, and is also converted to a fired ceramic state.

3. The method of claim 2, wherein the alumina material for the device and for the image-forming material are each independently selected from the group consisting of alpha alumina, β″-alumina (beta prime-prime alumina”), and combinations thereof.

4. The method of claim 3, wherein the alumina material for the device and for the image-forming material are both alpha alumina, or are both β″-alumina.

5. The method of claim 1, wherein heating step (b) is carried out under conditions sufficient to ensure conversion of the alumina material to at least about 95% of the β″-alumina form.

6. The method of claim 1, wherein the additive process comprises a direct-write technique.

7. The method of claim 6, wherein the direct-write process is selected from the group consisting of thermal spray, laser CVD, ink jet, laser particle guidance, matrix assisted pulsed laser evaporation (MAPLE), pen dispensing techniques, and combinations of any of the foregoing.

8. The method of claim 1, wherein the additive process comprises screen-printing.

9. The method of claim 1, wherein the image-forming material is in the form of a slurry.

10. The method of claim 9, wherein the slurry further comprises at least one colorant that is capable of withstanding the sintering temperature.

11. The method of claim 10, wherein the colorant is a high-temperature fluorescent dye.

12. The method of claim 11, wherein the dye comprises a rare earth oxide or chromium oxide.

13. The method of claim 1, wherein the pattern of the image-forming material is detectable under UV light.

14. The method of claim 1, wherein the electrochemical device is an energy storage device.

15. The method of claim 14, wherein the energy storage device is a high-temperature thermal battery.

16. The method of claim 15, wherein the component of the battery is an electrolyte separator structure.

17. The method of claim 16, wherein the device is a sodium metal halide battery; and the fixed image comprises a beta alumina material, and is applied to a surface of a tubular electrolyte also formed of beta″ alumina material; wherein the tubular electrolyte is disposed between a negative electrode and a positive electrode.

18. The method of claim 17, wherein the negative electrode comprises molten sodium; and the positive electrode comprises nickel.

19. A method of monitoring the location and status of a ceramic electrochemical cell component during its manufacture and during additional, optional processing stages, comprising the following steps:
(i) forming the component, from a ceramic powder or slurry, into a selected green state;
(ii) applying at least one identifying mark to a surface of the green component, by an additive process; and
(iii) heating the component at a sintering temperature to convert the component to a fired ceramic state, and to fix the identifying mark to the component surface, wherein the mark is readable by the human eye or by any machine-readable device.
